(19) United States
(12) Patent Application Publication
(10) Pub. No.: US 2008/0290483 A1
(43) Pub. Date: Nov. 27, 2008

(54) SEMICONDUCTOR DEVICE, LEADFRAME AND STRUCTURE FOR MOUNTING SEMICONDUCTOR DEVICE

(75) Inventor: Takahiro YURINO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/112,428

(22) Filed: Apr. 30, 2008

(30) Foreign Application Priority Data
May 25, 2007 (JP) 2007-138984

(51) Int. Cl. H01L 23/495; H05K 7/18

(52) U.S. Cl. 257/670; 361/813; 257/E23.037

(57) ABSTRACT

A structure of a semiconductor device is provided, where intervals can be narrowed between leads arranged around a semiconductor element to increase the number of leads, and electrical interference is prevented or reduced between the leads to cause no crosstalk between the leads. The semiconductor device of the present invention includes a semiconductor element and a plurality of leads arranged around the semiconductor element. The plurality of leads include a plurality of first leads and a plurality of second leads. The plurality of first leads are connected to electrode terminals of the semiconductor element through connection members. The plurality of second leads are arranged between the first leads and are not connected to the electrode terminals of the semiconductor element.

### CROSS-REFERENCE TO RELATED APPLICATIONS

This application is based upon and claims the benefits of the priority from the prior Japanese Patent Application No. 2007-138984 filed on May 25, 2007, the entire contents of which are incorporated herein by reference.

### BACKGROUND OF THE INVENTION

1. Field of the Invention

The present invention relates to a semiconductor device, a leadframe and a structure for mounting the semiconductor device and, more particularly, to a semiconductor device, a leadframe and a structure for mounting the semiconductor device, which ease fine pitch inner leads arrangement to increase the number of pins.

2. Description of the Related Art

As the performance of electronic equipment is improved with size reduction, fast and high performance semiconductor devices (e.g., a semiconductor integrated circuit device installed in the electronic equipment) are demanded with further size and weight reductions.

For example, external connection terminals (leads) need to be arranged in higher density even in a resin encapsulated semiconductor device, a type of semiconductor device.

To meet the demands, the external connection terminals (leads) are arranged in higher density around a die stage, which supports a semiconductor element (semiconductor chip), in the resin encapsulated semiconductor device.

A semiconductor device 600, an example of a conventional semiconductor device, is described with reference to FIGS. 8A and 8B.

FIG. 8A shows a leadframe of the semiconductor device 600 and an arrangement of a semiconductor element mounted on the leadframe. FIG. 8B shows an enlarged essential part of FIG. 8A.

In the semiconductor device 600, a semiconductor element 60 is mounted on and adhered to a rectangular die stage 72 of a leadframe 70, and die stage bars 71 support four corners of the die stage 72. Electrode terminals of the semiconductor element 60 are connected to leads 73 of the leadframe 70 through bonding wires 80.

The plurality of leads 73 are aligned on substantially the same plane around the die stage 72. Each lead 73 has sections called an inner lead 73A and an outer lead 73B through a tie bar (dambar) 74. The inner lead 73A is closer to the die stage 72 (inner side) than the outer lead 73B on an outer side.

This type of the semiconductor device may be called a quad flat package (QFP) semiconductor device, in which the plurality of leads 73 are arranged along four sides of the rectangular die stage 72.

Each inner lead 73A of the plurality of leads 73 is connected to the electrode terminal (e.g., a signal input/output terminal, a power terminal or an earth terminal) of the semiconductor element 60 through the bonding wire 80.

In the semiconductor device 600, intervals between the inner leads 73A of the leads 73 are narrowed so that the leads 73 are arranged in higher density (pitch) in the vicinity of the semiconductor element 60. This increases the number of the arranged leads 73. Thus, the performance of the semiconductor device 60 can be improved.

However, narrowing intervals between the leads 73 causes difficult lead formation as well as interference therebetween when the semiconductor device is in operation. This results in crosstalk.

To overcome this problem, die stage bars (support bars) are conventionally used as common terminals for ground (earth) leads, power leads and/or the like and extended parallel around the semiconductor element (e.g., refer to International Publication WO Nos. 98/31051 and 03/105226).

Thus, it is possible to reduce the number of leads and arrange the leads in appropriate density.

However, the extended die stage bars (support bars) cannot support the die stage in this case. Therefore, other support members need to support the semiconductor element.

Meanwhile, Japanese Patent Application Laid-Open (JP-A) No. 11-40721 discloses a structure where noise reduction metal pieces are arranged between the tips of the plurality of signal leads and embedded in encapsulating resin.

A member of the noise reduction metal pieces is different from that of the leads, and the metal pieces are connected to a die pad (die stage) through a connection conductor or a connection metal wire.

Thus, the semiconductor device fabrication becomes complicated, and the signal leads cannot be shielded sufficiently.

Moreover, JP-A No. 2006-19767 discloses a semiconductor device fabrication of high pin count quad flat non-leaded (QFN) package, in which leads with different lengths are alternately (two staggered rows) arranged around a die pad (die stage) to arrange a larger number of leads and a height of the wire loops is changed for connection.

In this semiconductor device, electrical interference occurs between the leads as in the conventional device shown in FIG. 8, but there are no countermeasures thereagainst.

The present invention overcomes the problems of the conventional semiconductor devices and achieves the objects described below.

An object of the present invention is to provide a structure of a semiconductor device, in which intervals are enabled to be narrowed between leads arranged around a semiconductor element to increase the number of leads, and electrical interference is prevented or reduced between the leads so that no crosstalk occurs between the leads.

Another object of the present invention is to provide a structure of a leadframe suitable for the structure of the semiconductor device.

Still another object of the present invention is to provide a mounting structure which exerts its effects even with the distinctive structure of the semiconductor device.

### BRIEF SUMMARY OF THE INVENTION

According to one aspect of an embodiment, a semiconductor device includes a semiconductor element; and a plurality of leads arranged around the semiconductor element, in which the plurality of leads include a plurality of first leads and a plurality of second leads, the plurality of first leads are connected to electrode terminals of the semiconductor element through connection members, and the plurality of second leads are arranged between the plurality of first leads and are not connected to the electrode terminals of the semiconductor element.

According to another aspect of the embodiment, a leadframe includes a die stage on which a semiconductor element is mounted; and a plurality of leads arranged around the die stage, in which the plurality of leads include a plurality of first leads and a plurality of second leads, the plurality of first leads are connected to electrode terminals of the semiconductor element, which is mounted on the die stage, through connection members, and the plurality of second leads are arranged between the plurality of first leads more distantly from the die stage than tips of the plurality of first leads and are not connected to the electrode terminals of the semiconductor element.

### BRIEF DESCRIPTION OF THE SEVERAL VIEWS OF THE DRAWINGS

FIG. 1A is a plan view showing a structure of a semiconductor device in a first example (Example 1) of the present invention before resin encapsulation.

FIG. 1B is an enlarged partial view of FIG. 1A.

FIG. 2 is an external perspective view showing the structure of the semiconductor device in the first example (Example 1) shown in FIGS. 1A and 1B.

FIG. 3A is a plan view showing a structure of a semiconductor device in a second example (Example 2) of the present invention before resin encapsulation.

FIG. 3B is an enlarged partial view of FIG. 3A.

FIG. 4A is a plan view showing a structure of a semiconductor device in a third example (Example 3) of the present invention before resin encapsulation.

FIG. 4B is an enlarged partial view of FIG. 4A.

FIG. 5A is a plan view showing a structure of a semiconductor device in a fourth example (Example 4) of the present invention before resin encapsulation.

FIG. 5B is an enlarged partial view of FIG. 5A.

FIG. 6 is an external perspective view showing a semiconductor device according to the present invention being mounted on a support substrate.

FIG. 7 is an enlarged partial plan view showing conductive patterns in the support substrate shown in FIG. 6.

FIG. 8A is a plan view showing a structure of a conventional semiconductor device before resin encapsulation.

FIG. 8B is an enlarged partial view of FIG. 8A.

### DETAILED DESCRIPTION OF THE INVENTION

A semiconductor device and a structure for mounting the same according to the present invention are detailed with examples. However, the scope and spirit of the present invention are not limited to these examples.

### Example 1

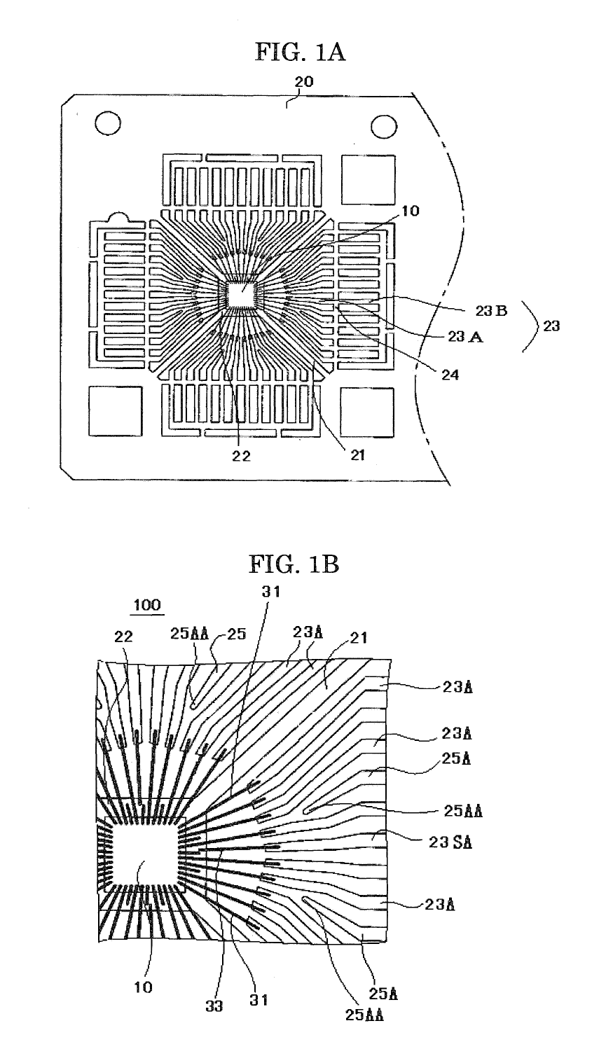

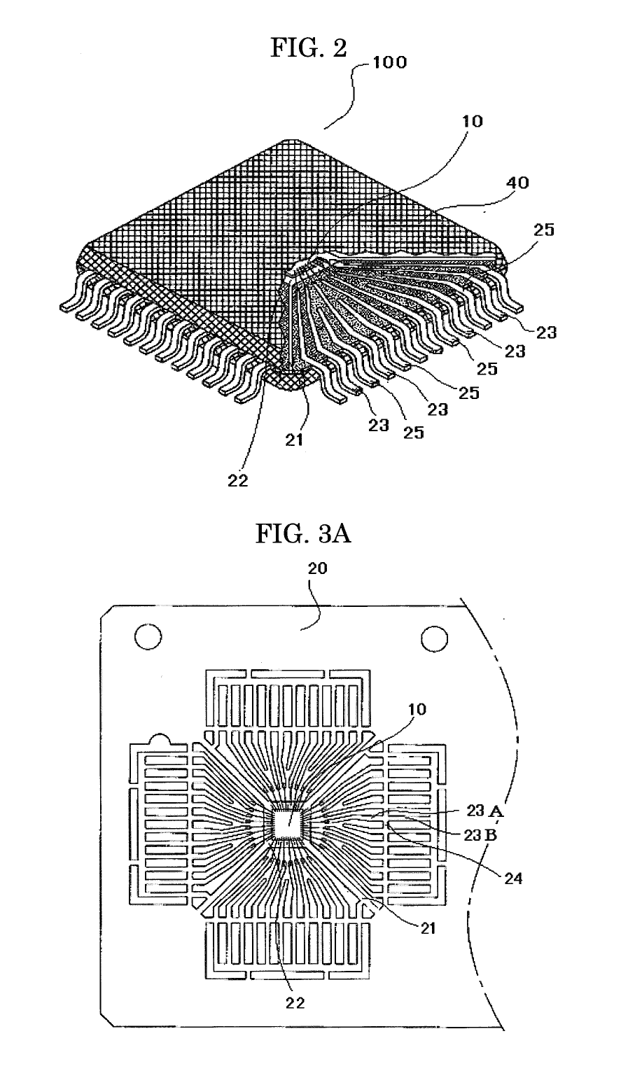

A semiconductor device 100, a first example of the semiconductor device according to the present invention, is described with reference to FIGS. 1A, 1B and 2.

FIG. 1A shows a leadframe of the semiconductor device 100 and an arrangement of a semiconductor element mounted on the leadframe. FIG. 1B shows an enlarged essential part of FIG. 1A.

In this example, a semiconductor element 10 is mounted on and adhered to a rectangular die stage 22 of a leadframe 20, and die stage bars 21 support four corners of the die stage 22. Electrode terminals of the semiconductor element 10 are connected to leads 23 of the leadframe 20 through bonding wires 31 and optionally to the die stage 22.

The plurality of leads 23 (first leads) are aligned on substantially the same plane around the die stage 22. Each lead 23 has sections called an inner lead 23A and an outer lead 23B through a tie bar (dambar) 24. The inner lead 23A is closer to the die stage 22 (inner side) than the outer lead 23B on an outer side.

As shown in the drawings, this type of semiconductor may be called a quad flat package (QFP) semiconductor device, in which the plurality of leads 23 are arranged along four sides of the rectangular die stage 22.

Each inner lead 23A of the plurality of leads 23 is connected to the electrode terminal (e.g., a signal input/output terminal, a power terminal or an earth terminal) of the semiconductor element 10 through the bonding wire 31.

Herein, leads 23S (inner leads 23SA), which have the same length as the leads 23, are arranged between the leads 23, and the tips of the inner leads 23SA are connected to the die stage 22 through bonding wires 33.

Surfaces of bonding areas of the inner leads 23A and inner leads 23SA are selectively silver (Ag) plated so that the bonding wires 31 and 33 can be connected to the inner leads 23A and 23SA, respectively.

The distinctive characteristics of the semiconductor device 100 in this example are as follows: leads 25 (second leads) are selectively arranged between the plurality of leads 23 (first leads) aligned on substantially the same plane around the die stage 22; and the leads 25 are not connected to the electrode terminals of the semiconductor element 10 through the bonding wires 31.

Each lead 25 also has sections called an inner lead and an outer lead through the tie bar (dambar) 24. The inner lead is closer to the die stage 22 (inner side) than the outer lead on an outer side.

The inner leads 25A of the leads 25 are shorter than the inner leads 23A of the leads 23.

Thus, the leads 23 are not arranged in lower density (pitch) in the vicinity of the die stage 22, in other words, in the vicinity of the semiconductor element 10.

The surfaces of the leads 25 are not silver (Ag) plated since the leads 25 are not connected to the electrode terminals of the semiconductor element 10 through the bonding wires 31.

The semiconductor element 10 which is adhered to and supported on the die stage 22 of the leadframe 20, the bonding wires 31, the leads 23 and the inner leads of the leads 25 are encapsulated with resin by known resin molding.

The leadframe 20 is made of copper (Cu) alloy or 42 alloy (iron (Fe)-42% Nickel (Ni) alloy).

Portions of the bonding wires 31, which are connected to the lead 23 of the leadframe 20, are silver (Ag) pre-plated.

The semiconductor element 10 is fabricated as follows: one of the main surfaces of a semiconductor base (e.g., made of silicon (Si) or gallium arsenide (GaAs)) is subjected to wafer process; and an active area (electronic circuit formation area) is formed. This active area includes active elements (e.g., a transistor), passive elements (e.g., a capacitative element) and an interconnection layer connecting these functional elements. Electrode terminals connected to the interconnection layer are arranged on one of the main surfaces of the semiconductor base.

The bonding wires 31 are thin alloy wires containing gold (Au), copper (Cu) and aluminum (Al) or any of these materials.

Moreover, an epoxy resin is used for the encapsulation.

After the resin encapsulation, the outer leads of the leads and the die stage bars 21 are cut off from the leadframe 20, the tie bars (dambars) 24 between the leads are removed, and the leads are shaped. Thus, the semiconductor device 100 shown in FIG. 2 is formed.

Note that an encapsulating resin 40 is partially removed in FIG. 2 to show the arrangements of leads 23 and 25 and the like in the semiconductor device 100.

Specifically, FIG. 2 shows that upper surfaces of the leads 23 and 25 are exposed from the same side as the semiconductor element 10 being mounted on the die stage 22.

As shown in FIG. 2, the leads 25 are not connected to the electrode terminals of the semiconductor element 10 in the semiconductor device 100. The leads 25 can be independently connected to external electrode terminals.

Thus, when the semiconductor device 100 is mounted on an interconnection board incorporated in electronic equipment or the like, it is possible to give a reference potential (e.g., an earth potential) to the leads 25 through sockets or the electrode terminals of the interconnection board.

Specifically, when a reference potential (e.g., an earth potential) is applied to the leads 25 in the semiconductor device 10 having this structure, it is possible to electrically shield the leads 23 on both sides of the leads 25. Thus, it is possible to prevent or reduce crosstalk between the leads 23.

As previously mentioned, the leadframe 20 used in this example includes the die stage 22 and the plurality of leads. The semiconductor element 10 is mounted on the die stage 22, and the plurality of leads are arranged around the die stage 22. The plurality of leads are constituted by the plurality of leads 23 (first leads) and leads 25 (second leads). The plurality of leads 23 are connected to the electrode terminals of the semiconductor element 10, which is mounted on the die stage 22, through connection members (e.g., bonding wires 31). The leads 25 are selectively arranged between the leads 23 and are not connected to the electrode terminals of the semiconductor element 10 through connection members.

Specifically, the leads 23 and the leads 25 are formed simultaneously in the leadframe 20. Thus, with the leadframe 20, it is possible to employ a conventional resin-encapsulated semiconductor device fabrication to efficiently manufacture the semiconductor device 100 without increasing the manufacturing costs.

### Example 2

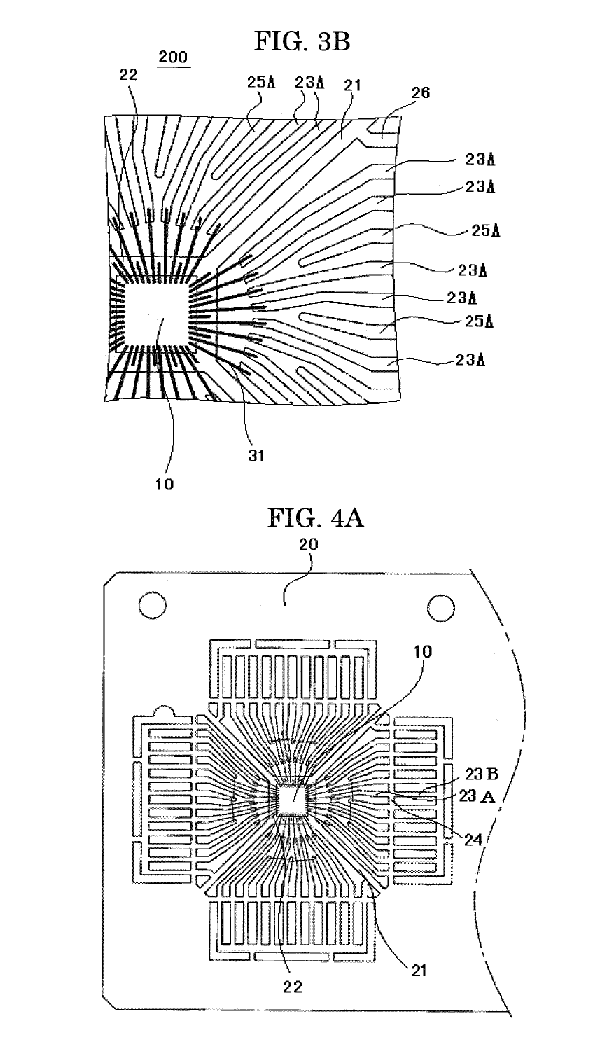

A semiconductor device 200, a second example of the semiconductor device according to the present invention, is described with reference to FIGS. 3A and 3B.

FIG. 3A shows a leadframe of the semiconductor device 200 and an arrangement of a semiconductor element mounted on the leadframe. FIG. 3B shows an enlarged essential part of FIG. 3A.

Note that the same reference numerals are used for components corresponding to those of the semiconductor device 100 shown in FIGS. 1A, 1B and 2.

Similar to the first example, a semiconductor element 10 is mounted on and adhered to a rectangular die stage 22 of a lead frame 20, and die stage bars 21 support four corners of the die stage 22. Electrode terminals of the semiconductor element 10 are connected to leads 23 of the leadframe 20 through bonding wires 31 and optionally to the die stage 22.

The plurality of leads 23 (first leads) are aligned on substantially the same plane around the die stage 22. Each lead 23 has sections called an inner lead 23A and an outer lead 23B through a tie bar (dambar) 24. The inner lead 23A is closer to the die stage 22 (inner side) than the outer lead 23B on an outer side.

Each inner lead 23A of the plurality of leads 23 is connected to the electrode terminal (e.g., a signal input/output terminal, a power terminal or an earth terminal) of the semiconductor element 10 through the bonding wire 31.

Similar to the first example, leads 25 (second leads) are selectively arranged between the plurality of leads 23 aligned on substantially the same plane, and the leads 25 are not connected to the electrode terminals of the semiconductor element 10.

Each lead 25 also has sections called an inner lead and an outer lead through the tie bar (dambar) 24. The inner lead is closer to the die stage 22 (inner side) than the outer lead on an outer side.

The distinctive characteristics of the semiconductor device 200 in this example are that leads 26 adjacent to the die stage bars 21 are merged with the die stage bars 21.

Thus, when a reference potential (e.g., an earth potential) is applied to the leads 26, as to the leads 25, after the semiconductor device is formed, the leads 23 on both sides of the die stage bars 25 are electrically shielded. Therefore, it is possible to prevent or reduce the crosstalk between the leads 23.

Moreover, it is unnecessary to arrange leads 23S (inner leads 23SA) of the first example since the leads 26 are arranged. Therefore, it is possible to arrange the leads 23 more easily.

### Example 3

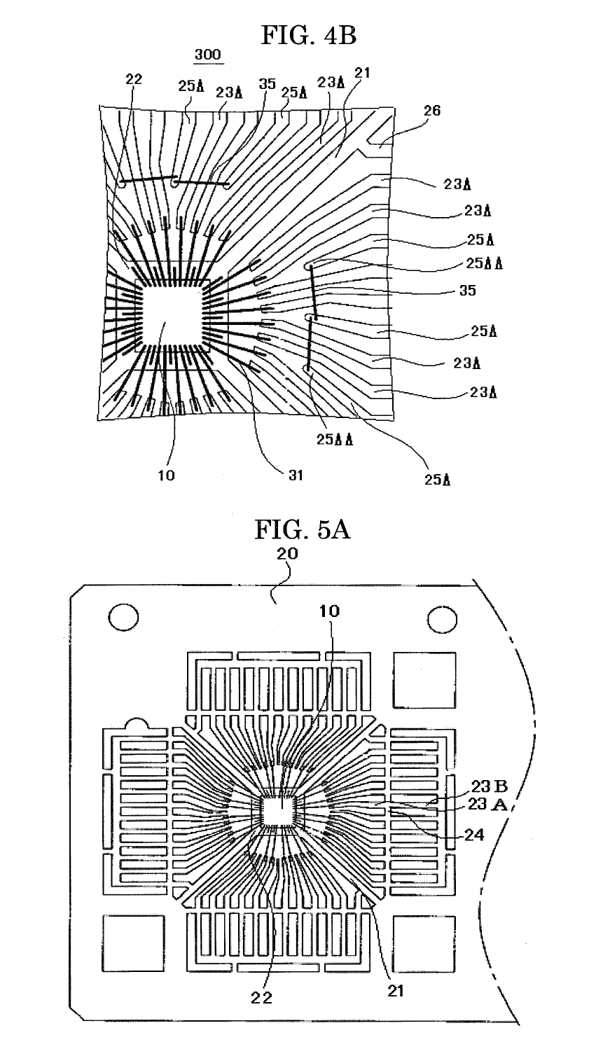

A semiconductor device 300, a third example of the semiconductor device according to the present invention, is described with reference to FIGS. 4A and 4B.

FIG. 4A shows a leadframe of the semiconductor device 300 and an arrangement of a semiconductor element mounted on the leadframe. FIG. 4B shows an enlarged essential part of FIG. 4A.

Note that the same reference numerals are used for components corresponding to those of the semiconductor devices 100 or 200 shown in FIGS. 1A, 1B, 2, 3A and 3B.

Similar to the first and second examples, a semiconductor element 10 is mounted on and adhered to a rectangular die stage 22 of a leadframe 20, and die stage bars 21 support four corners of the die stage 22. Electrode terminals of the semiconductor element 10 are connected to leads 23 of the leadframe 20 through bonding wires 31 and optionally to the die stage 22.

The plurality of leads 23 (first leads) are aligned on substantially the same plane around the die stage 22. Each lead 23 has sections called an inner lead 23A and an outer lead 23B through a tie bar (dambar) 24. The inner lead 23A is closer to the die stage 22 (inner side) than the outer lead 23B on an outer side

Each inner lead 23A of the plurality of leads 23 is connected to the electrode terminal (e.g., a signal input/output terminal, a power terminal or an earth terminal) of the semiconductor element 10 through the bonding wire 31.

Similar to the first and second examples, leads 25 (second leads) are selectively arranged between the plurality of leads 23 aligned on substantially the same plane, and the leads 25 are not connected to the electrode terminals of the semiconductor element 10.

Each lead 25 also has sections called an inner lead and an outer lead through the tie bar (dambar) 24. The inner lead is closer to the die stage 22 (inner side) than the outer lead on an outer side.

The distinctive characteristics of the semiconductor device 300 in this example are that connection members, bonding wires 35, interconnect the leads 25 selectively arranged between the leads 23.

Specifically, tips 25AA of the inner leads 25A of the lead 25, which are adjacent to the semiconductor element 10, are connected to one ends of the bonding wires 35. The other ends of the bonding wires 35 are connected to the tips 25AA of other leads 25 over the adjacent leads 23.

Since the tips 25AA are connected to the bonding wires 35, the surfaces of the tips 25AA of the leads 25 are silver (Ag) plated in this example.

The bonding wires 35 interconnect the tips 25AA of the plurality of leads 25 so that the leads 25 are present along the leads 23 in the maximum length and the shielding effect of the leads 25 becomes stronger.

If the bonding wires 35 interconnect the leads 25 at portions closer to the outer leads instead of the tips 25AA of the leads 25, the ends of the leads 23 become free respect to the semiconductor element 10. Thus, the shielding effect of the leads 25 is reduced.

Note that it is optional to arrange the bonding wires 35 on other portions of the leads 25 (e.g., portions closer to the outer leads) in addition to the tips 25AA of the leads 25. In other words, it is optional to align the plurality of bonding wires 35 on the leads 25 (not shown in the drawing).

The bonding wires 35 may be connected to the tips 25AA of the leads 25 before/after the plurality of electrode terminals of the semiconductor element 10 are connected to corresponding leads 23 through bonding wires 31. These steps may be alternately performed as necessary.

Note that FIGS. 4A and 4B show that leads 26 adjacent to the die stage bars 21 are merged with the die stage bars 21 as shown in the second example.

In addition to the interconnection of the leads 25, the leads 23 on both sides of the die stage bars 21 are electrically shielded more effectively by the above structure. Thus, it is possible to prevent or reduce the crosstalk between the leads 23.

Moreover, it is unnecessary to arrange leads 23S (inner leads 23SA) of the first example since the leads 26 are arranged. Therefore, it is possible to arrange the leads 23 more easily.

### Example 4

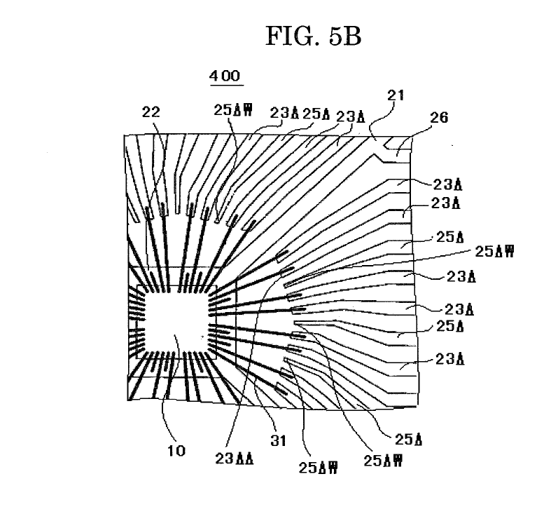

A semiconductor device 400, a fourth example of the semiconductor device according to the present invention, is described with reference to FIGS. 5A and 5B.

FIG. 5A shows a leadframe of the semiconductor device 400 and an arrangement of a semiconductor element mounted on the leadframe. FIG. 5B shows an enlarged essential part of FIG. 5A.

Note that the same reference numerals are used for components corresponding to those of the semiconductor devices 100, 200 and 300 shown in FIGS. 1A, 1B, 2, 3A, 3B, 4A and 4B.

Similar to the first to third examples, a semiconductor element 10 is mounted on and adhered to a rectangular die stage 22 of a leadframe 20, and die stage bars 21 support four corners of the die stage 22. Electrode terminals of the semiconductor element 10 are connected to leads 23 of the leadframe 20 through bonding wires 31 and optionally to the die stage 22.

The plurality of leads 23 (first leads) are aligned on substantially the same plane around the die stage 22. Each lead 23 has sections called an inner lead 23A and an outer lead 23B through a tie bar (dambar) 24. The inner lead 23A is closer to the die stage 22 (inner side) than the outer lead 23B on an outer side.

Each inner lead 23A of the plurality of leads 23 is connected to the electrode terminal (e.g., a signal input/output terminal, a power terminal or an earth terminal) of the semiconductor element 10 through the bonding wire 31.

Similar to the first to third examples, leads 25 (second leads) are selectively arranged between the plurality of leads 23 aligned on substantially the same plane, and the leads 25 are not connected to the electrode terminals of the semiconductor element 10.

Each lead 25 also has sections called an inner lead and an outer lead through the tie bar (dambar) 24. The inner lead is closer to the die stage 22 (inner side) than the outer lead on an outer side.

The distinctive characteristics of the semiconductor device 200 in this example are that the leads 25 are selectively arranged and extended between the leads 23, and tips 25AW of the leads 25 and tips 23AA of the leads 23 are arranged adjacent to the die stage 22 or the semiconductor element 10 in the approximately the same distance.

Since the leads 25 are not connected to bonding wires 31, the tips 25AW of the leads 25 are smaller (narrower) than the tips 23AA of the leads 23. Specifically, the widths of the tips 25AW of the leads 25 are equal to or less than 80% of the widths of the tips 23AA of the leads 23.

Since at least the tips 25AW of the leads 25 are small, density of the arranged tips 23AA of the leads 23 is not greatly reduced.

Since the leads 25 are arranged and extended to the vicinity of the tips of the leads 23, the leads 25 are present along the leads 23, which are on both sides of the leads 25, in approximately full length. Thus, the shielding effect of the leads 25 is exerted more effectively.

Note that FIGS. 5A and 5B show that leads 26 adjacent to the die stage bars 21 are merged with the die stage bars 21 as shown in the second example.

In addition to the arrangement of the extended leads 25, the leads 23 on both sides of the die stage bars 21 are electrically shielded more effectively by this structure. Thus, it is possible to prevent or reduce the crosstalk between the leads 23.

Moreover, it is unnecessary to arrange leads 23S (inner leads 23SA) of the first example since the leads 26 are arranged. Therefore, it is possible to arrange the leads 23 more easily.

### Example 5

A structure for mounting a semiconductor device according to the present invention is described in Example 5.

Herein, the semiconductor device 100 of the first example is employed. This example is based on a structure in which the semiconductor device 100 is installed or mounted on a support substrate such as a circuit board. As a matter of course, the semiconductor devices 200, 300 or 400 may be mounted in the same manner as the semiconductor device 100.

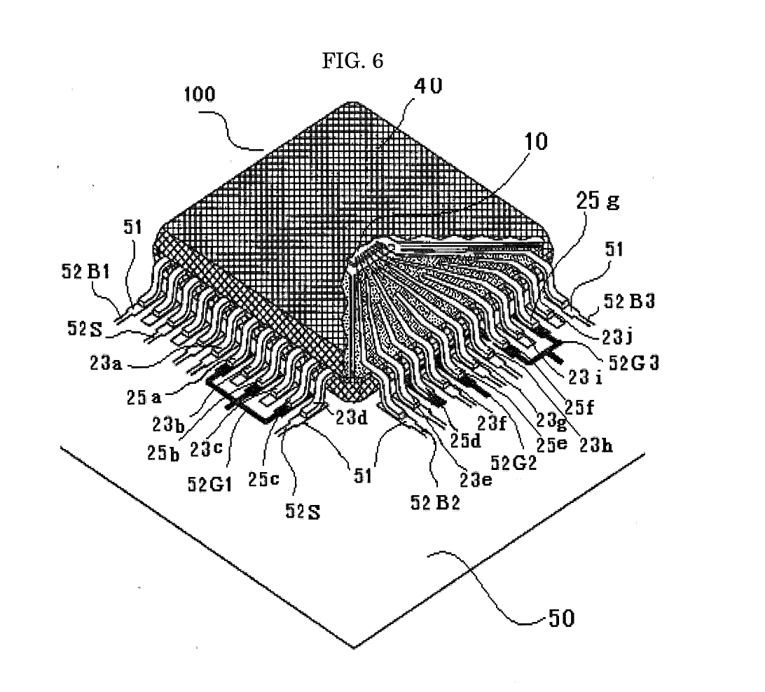

FIG. 6 shows the semiconductor device 100 being mounted on a support substrate 50 such as a circuit board.

Similar to FIG. 2, an encapsulating resin 40 of the semiconductor device 100 is partially removed in FIG. 6. Specifically, FIG. 6 shows that upper surfaces of leads 23 (first leads) and leads 25 (second leads) are exposed from the same side as a semiconductor element 10 being mounted on a die stage 22.

The semiconductor device 100 is mounted on the support substrate 50 by connecting and adhering outer leads 23B of the leads 23 and outer leads 25B of the leads 25 to corresponding terminals 51 on one of the main surfaces of the support substrate 50.

The support substrate 50 is an insulating base made from an organic insulating resin (e.g., a glass-epoxy resin, a glass-bismaleimide-triazine (BT) or polyimide) or an insulating inorganic material (e.g., ceramic or glass). A conductive layer is arranged on the front and/or back surface(s) and optionally inside (inner layer) the support substrate 50.

The conductive layer is mainly composed of copper (Cu). The surface of the conductive layer is subjected to two layer plating so that nickel (Ni) and gold (Au) layers are formed on the surface in this order from the lower layer.

The support substrate 50 may be called an interconnection board, a circuit board or an interposer.

The terminals 51 are connected to a conductive pattern arranged on one of the main surfaces (front surface) of the support substrate 50, the other main surface (back surface) thereof or inside the support substrate 50.

Before the semiconductor device 100 is mounted on the support substrate 50, the outer leads of the semiconductor device 100 and the terminals 51 of the support substrate 50 are pre-soldered. While the outer leads and the terminals 51 are in contact, the solder is fused again (reflow) so that they can be connected to each other.

In this mounting structure, the plurality of terminals 51 connected to the leads 23 and 25 in the semiconductor device 100 are selectively connected to conductive patterns 52S, conductive patterns 52B, conductive patterns 52G or the like. The conductive patterns 52S, 52B and 52G are connected to a signal potential, a power potential and an earth potential, respectively.

Specifically, the leads 23 connected to signal input/output terminals in the semiconductor device 100 are connected to the conductive patterns 52S. The leads 23 connected to the power terminals in the semiconductor device 100 are connected to the conductive patterns 52B. The leads 23 connected to the earth terminals in the semiconductor device 100 are connected to the conductive pattern 52G.

Meanwhile, the leads 25 are connected to the conductive patterns 52G connected to the earth potential.

As previously mentioned, the leads 25 are connected to the reference potential (e.g., the earth potential) so that the leads 23 arranged on both sides of the leads 25 can be shielded. Therefore, the performance characteristics of the semiconductor device can be improved.

As high performance of the electronic equipment is demanded nowadays, an increasing number of semiconductor devices incorporate a plurality of functional circuits.

In this case, the plurality of functional circuits need to be separated from a signal circuit and may require different working voltages.

To apply different working voltages from the outside, the plurality of functional circuits are connected to corresponding power circuits on the support substrate through different conductive patterns.

A reference potential is given to different functional circuits through different conductive patterns.

As for the semiconductor device 100 shown in FIG. 6, different reference potentials are given to the plurality of incorporated functional circuits.

Specifically, leads 25a to 25c arranged between leads 23a to 23d are commonly connected to a first conductive pattern 52G1 and further to a first reference potential through the first conductive pattern 52G1.

Moreover, leads 25d to 25e arranged between leads 23e to 23g are commonly connected to a conductive pattern 52Gs, which is arranged under the semiconductor element 100, and further to a second reference potential through a second conductive pattern 52G2.

Furthermore, leads 25f to 25g arranged between leads 23h to 23j are commonly connected to a third conductive pattern 52G3 and further to a third reference potential through the third conductive pattern 52G3.

The leads 25 are connected to the reference potentials (e.g., earth potentials) and arranged between the leads 23 as described so that the plurality of functional circuits in the semiconductor device 100 can perform their own necessary operations independently without causing the crosstalk between the leads.

Meanwhile, the first to third reference potentials may be interconnected on the support substrate 50 as necessary.

Note that FIG. 6 does not show a structure where the die stage bars 21 are connected to the reference potentials through the leads 26 as shown in FIG. 3 and the like. However, this structure may be optionally employed.

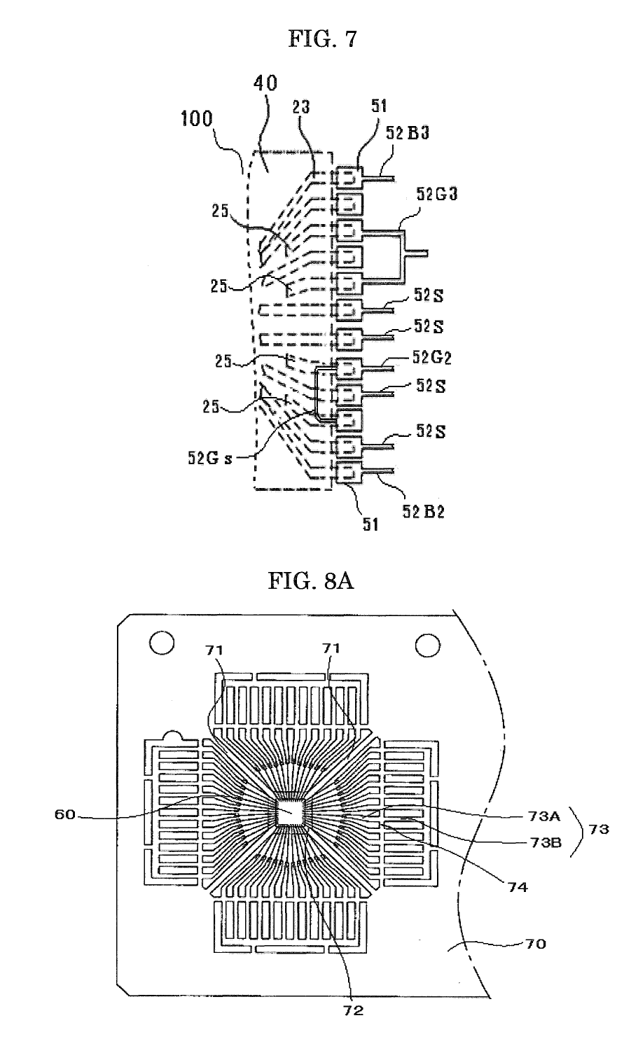

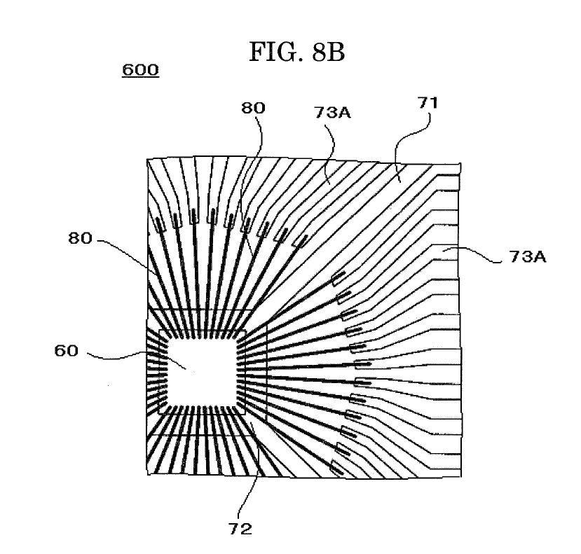

FIG. 7 shows the conductive pattern 52Gs arranged on the support substrate 50 as well as the conductive pattern 52G2.

Specifically, the conductive pattern 52Gs is arranged on the support substrate 50 under the semiconductor device 100 and interconnects the terminals 51 connected to the leads 25. For example, a U-shaped or a C-shaped conductive pattern 52Gs may be arranged.

The conductive pattern 52Gs can be formed not only as a conductive layer formed on the surface of the support substrate 50, but also as an inner conductive layer.

In the embodiments of the present invention described above, one semiconductor element is mounted on the die stage of the leadframe. However, the scope and spirit of the present invention are not limited to this structure.

The scope and spirit of the present invention can be applied to structures where a plurality of semiconductor elements are laminated on one die stage or a plurality of semiconductor elements are aligned and mounted on a large die stage or a plurality of consecutively arranged die stages.

By employing the semiconductor device, the leadframe and the structure for mounting the semiconductor device according to the present invention, fast and high performance of a resin-encapsulated semiconductor device installed in electronic equipment can be achieved with further size and weight reductions.

What is claimed is:

1. A semiconductor device comprising:
a semiconductor element; and
a plurality of leads arranged around the semiconductor element,
wherein the plurality of leads include a plurality of first leads and a plurality of second leads,
the plurality of first leads are connected to electrode terminals of the semiconductor element through connection members, and
the plurality of second leads are arranged between the plurality of first leads and are not connected to the electrode terminals of the semiconductor element.

2. The semiconductor device according to claim 1, wherein the plurality of first leads and the plurality of second leads are formed of same members.

3. The semiconductor device according to claim 1, wherein tips of the plurality of second leads are arranged more distantly from the semiconductor element than tips of the plurality of first leads.

4. The semiconductor device according to claim 1, wherein tips of the plurality of second leads are interconnected by connection members arranged over the plurality of first leads.

5. The semiconductor device according to claim 1,
wherein tips of the plurality of first leads are positioned in a vicinity of the semiconductor element, and tips of the plurality of second leads are positioned in the vicinity of the semiconductor device, and
the tips of the plurality of second leads are narrower than the tips of the plurality of first leads.

6. The semiconductor device according to claim 1, wherein die stage bars supporting a die stage, on which the semiconductor element is mounted, are connected to the plurality of second leads.

7. The semiconductor device according to claim 1, wherein a potential applied to the plurality of second leads is a reference potential.

8. A leadframe, comprising:
a die stage on which a semiconductor element is mounted; and
a plurality of leads arranged around the die stage,
wherein the plurality of leads include a plurality of first leads and a plurality of second leads,
the plurality of first leads are connected to electrode terminals of the semiconductor element, which is mounted on the die stage, through connection members, and
the plurality of second leads are arranged between the plurality of first leads more distantly from the die stage than tips of the plurality of first leads and are not connected to the electrode terminals of the semiconductor element.

9. The leadframe according to claim 8, wherein die stage bars supporting the die stage are connected to the plurality of second leads.

10. A leadframe, comprising:
a die stage on which a semiconductor element is mounted; and
a plurality of leads arranged around the die stage,
wherein the plurality of leads include a plurality of first leads and a plurality of second leads,
tips of the plurality of first leads are positioned in a vicinity of the die stage, and
tips of the plurality of second leads are positioned in the vicinity of the die stage and narrower than the tips of the plurality of first leads.
